(19) United States
(12) Patent Application Publication
(10) Pub. No.: US 2026/0036642 A1
(43) Pub. Date: Feb. 5, 2026

(54) SYSTEM AND METHOD FOR ADAPTIVE BATTERY PARAMETER OPTIMIZATION FOR ESTIMATING BATTERY PACK STATE OF CHARGE

(71) Applicant: Ford Global Technologies, LLC, Dearborn, MI (US)

(72) Inventors: Yonghua Li, Ann Arbor, MI (US); Imad Hassan Makki, Ann Arbor, MI (US); Pankaj Kumar, Canton, MI (US); Hadi Abbas, Ypsilanti, MI (US); Yan Wang, Ann Arbor, MI (US)

(21) Appl. No.: 18/789,844

(22) Filed: Jul. 31, 2024

(51) Int. Cl. G01R 31/396; G01R 31/382; H01M 10/44; H02J 7/00

(52) U.S. Cl. CPC G01R 31/396; G01R 31/382; H01M 10/443; H02J 7/00032; H02J 7/0048; H02J 7/007182; H02J 7/007194

(57) ABSTRACT

A method for controlling an electrified vehicle (EV) having a battery pack includes transmitting, by the EV, a plurality of battery operation characteristics to a remote server over a period of time during which the battery pack undergoes a plurality of charge-discharge operations, and charging and discharging the battery pack according to a power limit defined using an updated battery parameter estimated by the remote server from a former battery parameter, employed during the plurality of charge-discharge operations, using the plurality of battery operation characteristics.

### TECHNICAL FIELD

The present disclosure generally relates to monitoring parameters employed for estimating state of charge of a battery pack for an electrified vehicle.

### BACKGROUND

An electrified vehicle (EV) includes a battery pack, sometimes referred to as a traction battery, for providing power to electric motors to propel the EV. One or more operation characteristics of the battery pack, such as but not limited to, voltage, current, state of charge (SOC), and/or power limits can be detected using sensors and/or estimated using complex algorithms. With the operation characteristics, a vehicle control system controls charging-discharging operation of the EV.

### SUMMARY

In one form, the present disclosure is directed to a method for controlling an electrified vehicle (EV) having a battery pack. The method includes transmitting, by the EV, a plurality of battery operation characteristics to a remote server over a period of time during which the battery pack undergoes a plurality of charge-discharge operations, and charging and discharging the battery pack according to a power limit defined using an updated battery parameter estimated by the remote server from a former battery parameter, employed during the plurality of charge-discharge operations, using the plurality of battery operation characteristics.

In one form, the present disclosure is directed to a vehicle system for an electrified vehicle (EV) having a battery pack. The vehicle system includes a communication system and a vehicle controller. The communication system is configured to transmit a plurality of battery operation characteristics to a remote server over a period of time during which the battery pack undergoes a plurality of charge-discharge operations. The vehicle controller is configured to charge and discharge the battery pack according to a power limit defined using an updated battery parameter estimated by the remote server from a former battery parameter, employed during the plurality of charge-discharge operations, using the plurality of battery operation characteristics.

In one form, the present disclosure is directed to a system for an electrified vehicle (EV) having a battery pack. The system includes a remote server and a vehicle system having a communication system and vehicle controller. The remote server includes one or more computing devices configured to output an updated battery parameter for the EV. The communication system is configured to communicate with the remote server to, at least, transmit a plurality of battery operation characteristics to the remote server over a period of time during which the battery pack undergoes a plurality of charge-discharge operations. The vehicle controller is configured to charge and discharge the battery pack according to a power limit defined using the updated battery parameter estimated by the remote server from a former battery parameter, employed during the plurality of charge-discharge operations, using the plurality of battery operation characteristics.

### BRIEF DESCRIPTION OF THE DRAWINGS

FIG. 1 is a block diagram of an example EV in accordance with the present disclosure in accordance with the present disclosure;

FIG. 2 is a block diagram of battery management module of the EV and an EV support server in accordance with the present disclosure; and

FIG. 3 is an example adaptive battery parameter evaluation routine in accordance with the present disclosure.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

A battery management module (BMM) of an EV is configured to estimate selected operation characteristics such as, but not limited to, the SOC of a battery pack, a power limit, an open circuit voltage (OCV), and/or a state of health (SOH), using predefined models/algorithms having one or more battery parameters. Overtime and usage, the battery cells of the battery pack age such that electrical properties of the battery cells (e.g., capacity and/or resistance) change. While battery parameters that are indicative of some of those electrical properties, are used to estimate operation characteristics like SOC, the values of the battery parameters stay the same, which may lead to inaccurate or drifting SOC values.

In one form, the present disclosure is directed to a system/method for providing an updated battery parameter using a battery model evaluation (BME) module that is configured to evaluate battery operation characteristic for a given EV and provide the updated battery parameter when a transmission condition is met. For example, the transmission condition may include a lapse of defined period of time or a parameter differential being detected. That is, estimations performed by a BMM of the given EV may be provided as an inner loop when the EV is being charged/discharged and an EV support server having the BME module is provided as an outer loop to provide updated battery parameters when applicable. The updated parameters are based on an evaluation one or more battery operation characteristics for the specific EV, and adjusting the battery parameter based on an operation differential detected between an estimated operation characteristic provided by the BME module and the operation characteristic provided by the EV. Using the operation differential, the battery parameter is adjusted to obtain the updated battery parameter for the BMM.

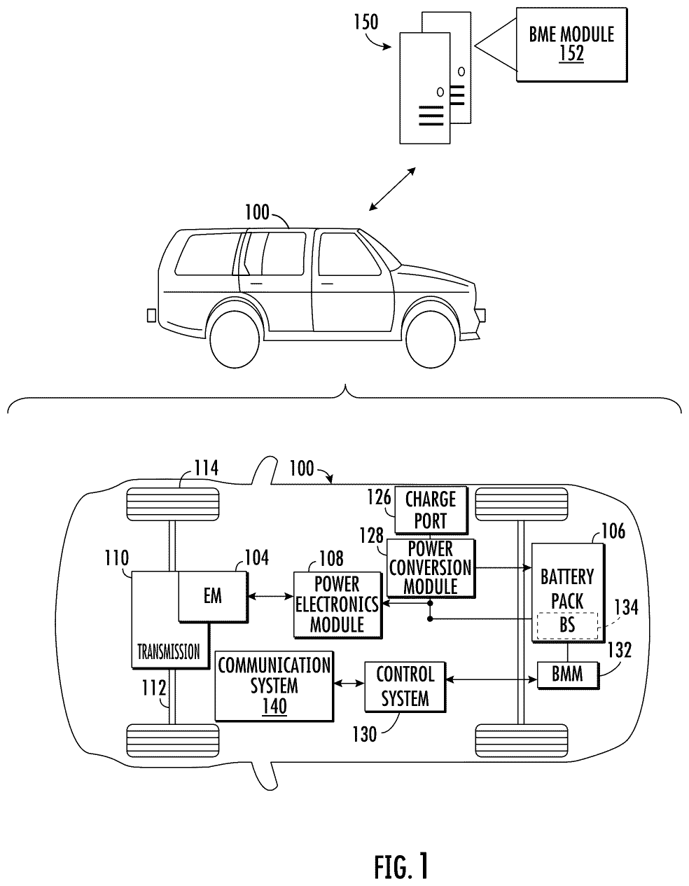

Referring to FIG. 1, in one form, an EV 100 is provided as a full battery electric vehicle (BEV) powered by electric machines. In a non-limiting example, the EV 100 includes a powertrain system having one or more electric machines 104 (e.g., electric motor), a battery pack 106, and a power electronics module 108. The EV 100 of the present disclosure does not include an engine, and thus, the battery pack 106 provides all of the propulsion power. In other variations, the present disclosure may be applied to other types of EVs such as a hybrid electric vehicle (plug-in or non-plug-in) having an engine, fuel cell electric vehicles (FCEV), and therefore, is not limited to pure battery powered EVs. In addition, the EV is not limited to four-wheel automobiles and may apply to scooters, vehicles having one or more wheels, aerial vehicles, and/or among other vehicles.

The electric machines 104 provides power movement of the EV 100, and in a non-limiting example, is mechanically connected to a transmission 110 that is mechanically connected to a drive shaft 112, which is mechanically connected to wheels 114 of the EV 100. In addition to providing propulsion power, the electric machines 104 may be configured to operate as a generator to recover energy that may normally be lost as heat in a friction braking system of EV 100.

The battery pack 106 provides a high-voltage (HV) direct current (DC) output that is employed to power the electric machines 104 via the power electronics module 108, and while one battery pack 106 is shown, the EV 100 may include multiple battery packs. In one form, the power electronics module 108, which includes an inverter, provides a bidirectional transfer energy between the battery pack 106 and the electric machines 104. Specifically, as known, the power electronics module 108 converts the DC voltage to a three-phase AC current to operate the electric machines 104, and in a regenerative mode, the power electronics module 108 converts three-phase AC current from the electric machines 104, which is acting as a generator, to DC voltage compatible with the battery pack 106.

The EV 100 may further include a power conversion module 128 that is an on-board charger having a DC/DC converter to condition power supplied from an external power source (e.g., the power grid/network) via a charge port 126, and provide the proper voltage and current levels to the battery pack 106. In an illustrative example, the charge port 126 is connective to an electric vehicle supply equipment (not shown), which draws power from the power source and supplies it to the EV through the charge port 126 and the power conversion module 128.

In one form, the EV 100 includes a control system 130 to coordinate the operation of the various components. The control system 130 includes electronics and software to perform the necessary control functions for operating the EV 100. The control system 130 may be a combination vehicle control system and powertrain control module (VSC/PCM). Although the control system 130 is shown as a single device, the control system 130 may include multiple controllers in the form of multiple hardware devices, or multiple software controllers with one or more hardware devices. In this regard, a reference to a “controller” herein may refer to one or more controllers.

In one form, the BMM 132 is in communication with one or more sensors (also referred to as a battery sensor (BS) 134 provided with the battery pack 106 to detect one or more operation characteristics of the battery pack 106, such as but not limited to, electric current, voltage, and/or temperature.

The EV 100 may further include a battery management module (BMM) 132 configured to estimate one or more operation characteristics of the battery pack 106 using, for example, data from the BS 134 and a series of algorithms or a battery model. For example, the BMM 132 is configured to estimate an open circuit voltage and a state of charge (SOC) of the battery pack 106 as additional operation characteristic of the battery pack.

In one form, the BMM 132 provides the SOC or a power limit defined using the SOC to the control system 130, which controls operation of the battery pack 106 (e.g., control charging/discharging of the battery pack 106). In a non-limiting example, during drive operation, the BMM 132 provides operation characteristics such as, but not limited to, power limit and/or SOC, to the control system 130, which determines how much power to draw from the battery pack 106. During a charge operation, the BMM 132 notifies the control system 130 of how much power is needed to charge the battery pack 106. While illustrated separate from the control system 130, the BMM 132 may be integrated with the control system 130. In one form, the BMM 132 and the control system 130 may be referred to as a vehicle controller.

In addition to components/system for controlling the drive operation of the EV 100, the EV 100 also includes other systems for performing other supportive functions. In a non-limiting example, the EV 100 includes a communication system 140 that is configured to exchange information with external devices or systems using wired/wireless communication (e.g., BLUETOOTH, ultra-wide band, cellular, and/or WIFI). In one form, the communication system 140 exchanges messages with an EV support server 150 having a battery model evaluation (BME) module 152. Accordingly, the communication system 140 may include a router, a modem, an antenna(s), an input-output interface, a universal serial bus (USB) port, and/or other suitable devices for supporting wireless and wired communication.

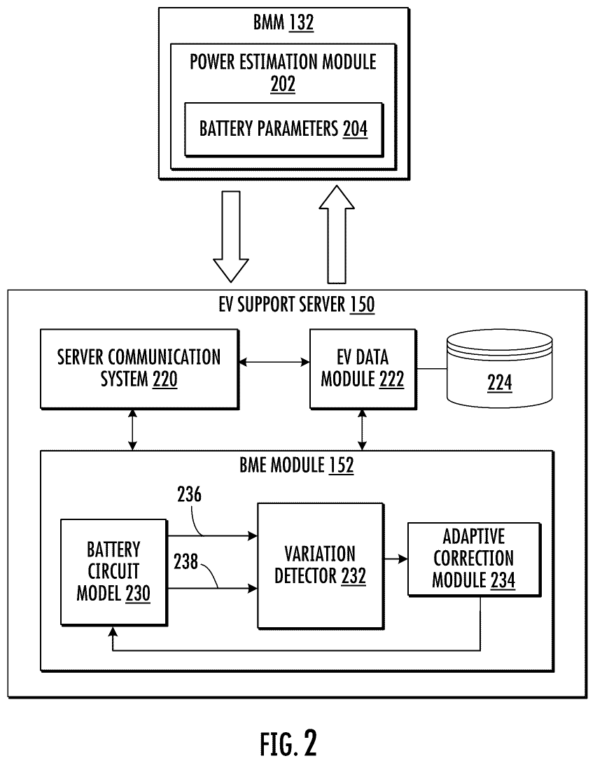

Referring to FIG. 2, in one form, the BMM 132 is configured to includes a power estimation module 202 for estimating the SOC and/or power limit of the battery pack 106 using one or more battery parameters 204. In a non-limiting example, the power estimation module 202 is defined by a series of algorithms that are based on a circuit representation of the battery pack 106 having one or more resistance-capacitance pairs. The series of algorithms of the power estimation module 202 are defined by one or more battery parameters such as but not limited to a battery internal resistance (R0), one or more resistance-capacitance (RC) pair resistance (R1, R2, . . . , RN), and/or one or more RC pair capacitance (e.g., C1, C2, . . . CN). Input variables of the power estimation module 202 may include temperature, voltage of one or more battery cells, current of one or more battery cells, and/or an open-circuit voltage that may be measured or estimated by the power estimation module 202 using for example a look-up table or OCV algorithms.

In some variations, if the power estimation module 202 includes multiple RC pairs as part of the circuit representation, the power estimation module is configured to obtain R1 and C1 from the BME module 152, and estimate additional parameters (e.g., R0, R2, C2, SOC) using, at least, data from the BS 134.

In one form, the EV support server 150 is a cloud-based server configured to exchange information with one or more EVs 100. In a non-limiting example, in addition to the BME module 152, the EV support server 150 includes a server communication system 220 and an EV data module 222 configured to store and manage data, received from one or more EVs 100, in EV datastore 224.

In one form, the server communication system 203 is configured to exchange information with one or more EVs 100 using wireless communication (e.g., BLUETOOTH, ultra-wide band, cellular, and/or WIFI), and may include a router, a modem, an antenna, an input-output interface, a universal serial bus (USB) port, and/or other suitable devices for supporting wireless communication. With respect to each EV 100, the server communication system 203 receives messages including data indicative of a vehicle identifier to uniquely identify the EV 100, the battery operation characteristic having a timestamp, and/or values of presently used battery parameters. As detailed herein, when applicable, the server communication system 220 transmits an updated battery parameter to a desired EV 100 based on information from the BME module 152.

The EV data module 222 is configured to store the battery operation characteristics from each EV 100 in the EV datastore 224, and retrieves the appropriate data for analysis by the BME module 152. In a non-limiting example, when the battery operation characteristics is received, the EV data module 222 is configured to retrieve historical data associated with the EV 100 using the vehicle identifier, which is used to associate the stored battery operation characteristics with the related EV 100. Once evaluated by the BME module 152, the EV data module 22 is configured to store the outputs of the BME module 152 and the operation characteristics in the datastore 224 for future use.

The BME module 152 is configured to monitor the battery parameters 204 employed by the power estimation module 202 during a period of time in which the battery pack 106 undergoes a plurality of charge-discharge operations. If applicable, the BME module 152 provides one or more updated battery parameter(s) to be employed by the power estimation module 202 in lieu of a former battery parameter employed during the plurality of charge-discharge operations. In a non-limiting example, the BME module 150 includes a battery circuit model 230, a variation detector 232, and an adaptive correction module 234.

The battery circuit model 230 is configured to estimate a SOC and a predicted voltage using one or more of the battery operation characteristics from the EV 100. In a non-limiting example, the battery circuit model 230 is a closed-loop nRC circuit model in which “n” represents the number of RC pairs used in the model. The closed-loop nRC circuit model may receive, as inputs, at least one of: current; temperature; a reference SOC point; SOC(0) which is the SOC measured at last recorded charging, is estimated using OCV, or is a last estimated SOC by the circuit model 230; a measured voltage trace that is a measured time series data of voltage captured by the BS 134. The closed-loop nRC circuit model outputs an estimated SOC 236 of the battery pack 106 and a predicted voltage 238 of the battery pack 106.

For the estimations, the battery circuit model 230 employs one or more of the same battery parameters as those employed by the power estimation module 202 (e.g., battery parameters 204). For example, for the nRC circuit model, the value of the battery internal resistance (e.g., R0), one or more RC pair resistance (R1, R2, . . . , RN), and one or more RC pair capacitance (C1, C2, . . . , CN) are the same as respective battery parameters 204.

The variation detector 232 is configured to detect an operation differential between at least one selected operation characteristic provided by the EV 100 and an estimated characteristic defined by the battery circuit model 230. In one form, the selected operation characteristics and the estimated characteristics are indicative of at least one of a SOC of the battery pack 106 or a voltage of the battery pack 106. That is, with the battery circuit model 230 being the nRC-type model, the variation detector 232 compares the predicted voltage 238 and the estimated SOC 236 with a measured voltage and an estimate SOC from the EV 100 to obtain a difference or drift. The variation detector 232 is configured to calculate a difference or a drift between the two values (e.g., a difference between the values from the battery circuit model 230 and the values from the EV 100). For example, “ΔV” is the difference in voltage between the predicted voltage 238 and the voltage from the EV and “ΔSOC” is the difference between the estimated SOC 236 and the SOC from the EV 100.

Using the difference/drift, the adaptive correction module 234 is configured to revise the battery parameter being employed to reduce the difference. That is, in one form, the adaptive correction module 234 is configured to define one or more estimated battery parameters using the operation differential. In a non-limiting example, the adaptive correction module 234 employs gradient based optimization to reduce the differential of the SOC and/or the voltage, where the gradient based optimization employs an appropriate step size and value for reducing the difference.

Once the battery parameter is estimated, the adaptive correction module 234 determines if the estimated battery parameter is to be transmitted to the EV 100 as an updated battery parameter. In one form, the one or more updated battery parameters are to be transmitted in response to a transmission condition being met. That is, while the adaptive correction module 234 actively monitors the battery parameters, the battery parameter may initially not change or change slightly, and so, the adaptive correction module 234 provides the estimated battery parameters, as updated battery parameters, when the transmission condition is met.

In a nonlimiting example, the transmission condition may include at least one of: a lapse of a defined period of time (e.g., 3 months, 6 months); detecting a difference between the estimated battery parameter and the present battery parameter being greater than or equal to a parameter drift threshold (e.g., 2% difference, 5% difference); an age of the battery pack 106 and the predefined period of time, such that as the age of the battery pack 106 increases the frequency at which the battery parameter is updated increases; and/or the number of times the battery pack 106 is being charged or discharged (e.g., the usage of the EV 100 may affect the life of the battery pack 106 and thus, the usage along with other conditions such as time or drift can be used to initiate an update). If the estimated battery parameter(s) is transmitted to the EV 100, the estimated SOC is used in the next iteration as SOC(0) and the battery parameters employed by the battery circuit model 230 are also updated.

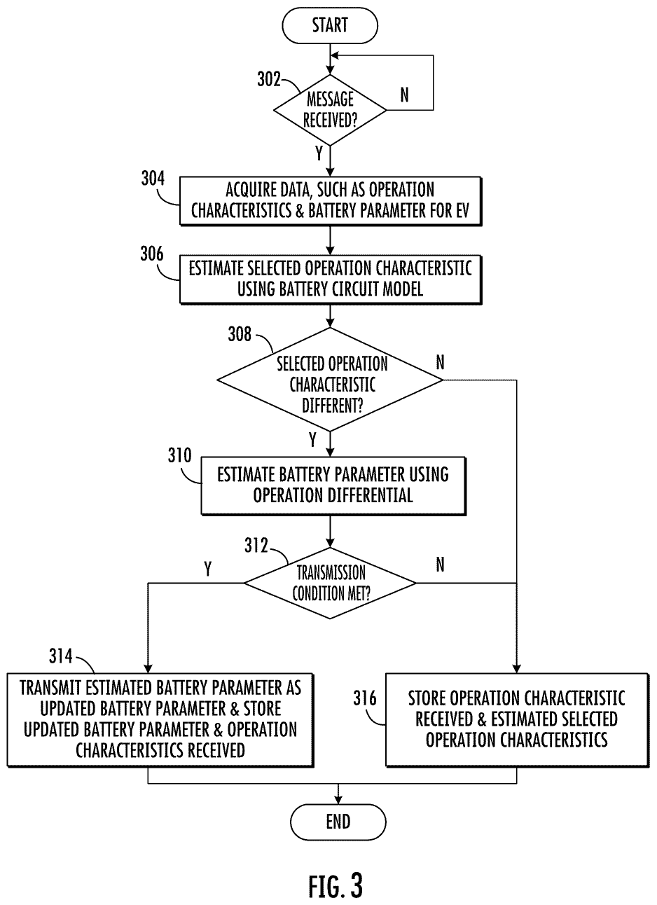

Referring to FIG. 3, an example adaptive battery parameter evaluation routine 300 performed by the EV support server 150 of the present disclosure is provided. At operation 302, the EV support server 150 determines if data indicative of operation characteristics is received from the EV 100.

At operation 304, the server 150 acquires data associated with the EV 100 providing the message. For example, using the vehicle identifier in the message, the server 150 obtains battery parameters and the operation characteristic transmitted with the message received.

At operation 306, the server 150 estimates selected operation characteristic using a battery circuit model 230. In a non-limiting example, the battery circuit model 230 is an nRC type model that outputs the estimated SOC 236 and the predicted voltage 238 as the selected operation characteristic.

At operation 308, the server 150 determines if the selected operation characteristic is different from respective operation characteristics provided by the EV 100 (e.g., SOC and voltage from the EV 100).

If there is a difference, the server 150, at operation 310, estimates a battery parameter using the operation differential (e.g., ΔV or ΔSOC). In a non-limiting example, the server 150 adjusts the battery parameter 204 presently being used by the EV 100 such that the operation differential (e.g., ΔV and/or ΔSOC) is reduced.

At operation 312, the server 150 determines whether a transmission condition for transmitting the estimated battery parameters as updated battery parameters to the EV 100, is met. In a non-limiting example, the server 150 determines if a defined period of time has lapsed since the last update of the battery parameter and/or if a difference of the estimated battery parameter and the presently used battery parameter is greater than or equal to a parameter drift threshold.

If the transmission condition is met, the server 150, at operation 314, transmits the updated battery parameter to the EV 100, which in return employs the updated battery parameter for defining the power limit of the battery pack 106, which is further used to charge and discharge the battery pack 106. The server 150 further used the updated battery parameter for the battery circuit model 230 and stored data, such as the operation characteristic received and/or the operation differential for future analysis.

If there is no difference in the selected operation characteristic (e.g., ΔV=0 or ΔSOC=0) or the transmission condition is not met, the server 150, at operation 316, stores the operation characteristic received in association with the EV 100 for future use. Other data may also be stored, such as, but not limited to, estimated selected operation characteristic and/or the estimated battery parameter.

The EV support server 150 having the BME module 152 of the present disclosure is configured to actively adjust the battery parameters used by the BMM 132 to reduce, for example SOC or voltage variation. The BME module 152 is adaptive to capture the changing behavior of the battery pack 106 not only throughout its operation during a trip, but also as the battery pack 106 ages with time. Moreover, because the battery parameter is adjusted for each EV 100 using data from that EV 100, the BME module 152 inherently accounts for battery-to-battery variations by avoiding population-level calculations (e.g., using operation characteristics or trends from other EVs).

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

In this application, the term “module” and/or “controller” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The term memory or memory device is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read only circuit), volatile memory circuits (such as a static random access memory circuit or a dynamic random access memory circuit), magnetic storage media (such as an analog or digital magnetic tape or a hard disk drive), and optical storage media (such as a USB, CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method for controlling an electrified vehicle (EV) having a battery pack, comprising:
transmitting, by the EV, a plurality of battery operation characteristics to a remote server over a period of time during which the battery pack undergoes a plurality of charge-discharge operations; and
charging and discharging the battery pack according to a power limit defined using an updated battery parameter estimated by the remote server from a former battery parameter, employed during the plurality of charge-discharge operations, using the plurality of battery operation characteristics.

2. The method of claim 1, further comprising transmitting, by the remote server, the updated battery parameter to the EV in response to at least one of a lapse of a defined time period or a difference between the former battery parameter and the updated battery parameter being greater than or equal to a parameter drift threshold.

3. The method of claim 1, further comprising defining, by the remote server, an estimated battery parameter using the plurality of battery operation characteristics in response to an operation differential detected between at least one selected operation characteristic among the plurality of battery operation characteristics and an estimated operation characteristic defined by the remote server.

4. The method of claim 3, wherein the at least one selected operation characteristic and the estimated characteristic is indicative of at least one of a state of charge of the battery pack or a voltage of the battery pack.

5. The method of claim 3, wherein the estimated operation characteristic is detected using a resistance-capacitor circuit representation of the battery pack.

6. The method of claim 1, wherein the plurality of battery operation characteristics includes at least one of a voltage of the battery pack, a current of the battery pack, an open circuit voltage, a state of charge, or a temperature.

7. The method of claim 1, wherein the remote server is configured to store the plurality of battery operation characteristics from each EV among a plurality of EVs, and only employ the plurality of battery operation characteristics for the EV in defining the updated battery parameter.

8. The method of claim 1, wherein the updated battery parameter includes at least one of a battery internal resistance, one or more resistance-capacitance (RC) pair resistance, or one or more RC pair capacitance.

9. A vehicle system for an electrified vehicle (EV) having a battery pack, comprising:
a communication system configured to transmit a plurality of battery operation characteristics to a remote server over a period of time during which the battery pack undergoes a plurality of charge-discharge operations; and
a vehicle controller configured to charge and discharge the battery pack according to a power limit defined using an updated battery parameter estimated by the remote server from a former battery parameter, employed during the plurality of charge-discharge operations, using the plurality of battery operation characteristics.

10. The vehicle system of claim 9, wherein the communication system is configured to obtain the updated battery parameter from the remote server in response to at least one of a lapse of a defined time period or a difference between the former battery parameter and the updated battery parameter being greater than or equal to a parameter drift threshold.

11. The vehicle system of claim 9, wherein the plurality of battery operation characteristics includes at least one of a voltage of the battery pack, a current of the battery pack, an open circuit voltage, a state of charge, or a temperature.

12. The vehicle system of claim 9, wherein the updated battery parameter is defined only using the plurality of battery operation characteristics from the EV.

13. The vehicle system of claim 9, wherein the updated battery parameter includes at least one of a battery internal resistance, one or more resistance-capacitance (RC) pair resistance, or one or more RC pair capacitance.

14. A system for an electrified vehicle (EV) having a battery pack, comprising:
a remote server including one or more computing devices configured to output an updated battery parameter for the EV; and
a vehicle system configured to control the EV and including:
a communication system configured to communicate with the remote server to, at least, transmit a plurality of battery operation characteristics to the remote server over a period of time during which the battery pack undergoes a plurality of charge-discharge operations; and
a vehicle controller configured to charge and discharge the battery pack according to a power limit defined using the updated battery parameter estimated by the remote server from a former battery parameter, employed during the plurality of charge-discharge operations, using the plurality of battery operation characteristics.

15. The system of claim 14, wherein the one or more computing devices of the remote server is configured to define an estimated battery parameter using the plurality of battery operation characteristics in response to an operation differential detected between at least one selected operation characteristic among the plurality of battery operation characteristics and an estimated operation characteristic defined by the remote server.

16. The system of claim 15, wherein the at least one selected operation characteristic and the estimated characteristic is indicative of at least one of a state of charge of the battery pack or a voltage of the battery pack.

17. The system of claim 14, wherein the updated battery parameter is transmitted to the EV in response to at least one of a lapse of a defined time period or a difference between the former battery parameter and the updated battery parameter being greater than or equal to a parameter drift threshold.

18. The system of claim 14, wherein the plurality of battery operation characteristics includes at least one of a voltage of the battery pack, a current of the battery pack, an open circuit voltage, a state of charge, or a temperature.

19. The system of claim 14, wherein the remote server is configured to store the plurality of battery operation characteristics from each EV among a plurality of EVs, and only employ the plurality of battery operation characteristics for the EV in defining the updated battery parameter.

20. The system of claim 14, wherein the updated battery parameter includes at least one of a battery internal resistance, one or more resistance-capacitance (RC) pair resistance, or one or more RC pair capacitance.
